(19) United States
(12) Patent Application Publication
(10) Pub. No.: US 2004/0115946 A1
(43) Pub. Date: Jun. 17, 2004

(54) Use of a sulfuric acid clean to remove titanium fluoride nodules

(76) Inventor: Lindsey H. Hall, Plano, TX (US)

Correspondence Address: TEXAS INSTRUMENTS INCORPORATED, P O BOX 655474, M/S 3999, DALLAS, TX, 75265

(21) Appl. No.: 10/320,122

(22) Filed: Dec. 16, 2002

(51) Int. Cl. H01L 21/302; H01L 21/461

(52) U.S. Cl. 438/715

(57) ABSTRACT

An embodiment of the invention is a method for cleaning high-density capacitors, 3, on a semiconductor wafer with sulfuric acid.

### BACKGROUND OF THE INVENTION

This invention relates to the removal of titanium fluoride nodules from a high-density capacitor.

### BRIEF DESCRIPTION OF THE DRAWINGS

FIG. 1 shows a portion of a semiconductor wafer with a high-density capacitor that has titanium fluoride nodules.

FIG. 2 shows a portion of a semiconductor wafer with a high-density capacitor after a sulfuric acid cleaning process.

### DETAILED DESCRIPTION OF THE INVENTION

Cleaning a semiconductor wafer with sulfuric acid removes the titanium fluoride nodules located on the high-density capacitors. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known strictures or operations are not shown in detail to avoid obscuring the invention.

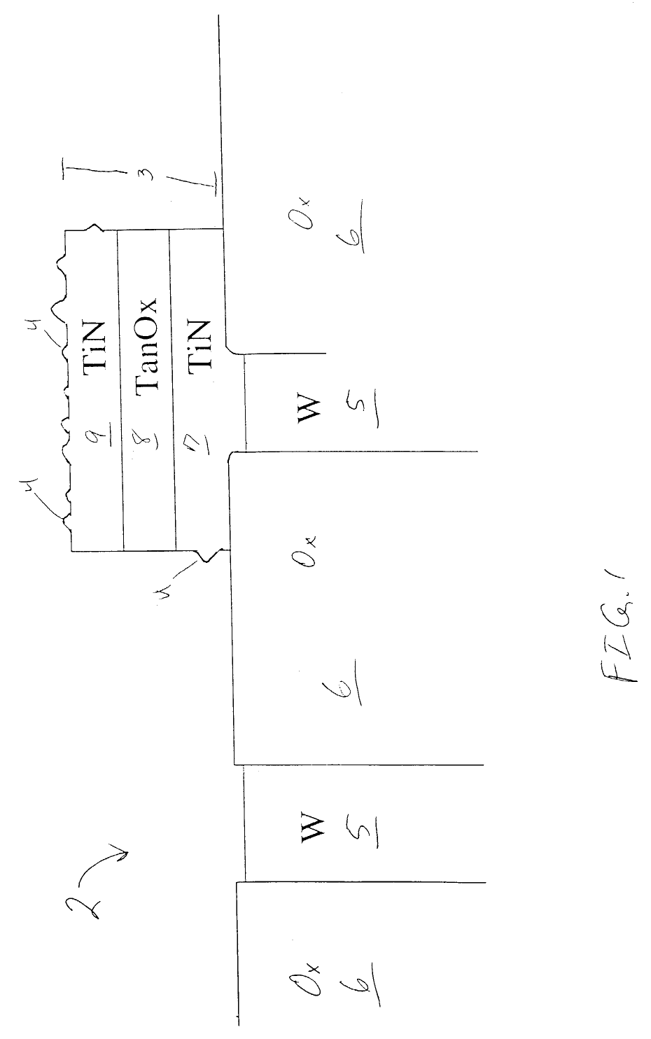

Referring to the drawings, FIG. 1 shows a portion of a semiconductor wafer, 2, with a high-density capacitor, 3, that has titanium fluoride nodules, 4. More specifically, wafer portion, 2, is the interconnect region of a semiconductor wafer. The contacts and first layer metal interconnects, 4, are made from a conductive material such as copper. The interconnect insulating material, 6, is a dielectric that insulates the electrical activity occurring on the contacts and interconnects, 5. For example, the interconnect insulating material, 6, may be Poly-Silicon Glass (“PSG”).

The high-density capacitor, 3, includes a titanium nitride bottom electrode, 7, a tantalum pentoxide dielectric, 8, and a titanium nitride top electrode, 9. Semiconductor wafer manufacturing processes, such as the fluorocarbon plasma etch or the fluorocarbon clean, cause the growth of titanium fluoride nodules, 4 on the high-density capacitor, 3. These titanium fluoride nodules, 4, may cause capacitor leakage and may also prevent reliable connections between the top electrode, 9, and the metal contacts or interconnects (not shown) that are formed in subsequent manufacturing processes.

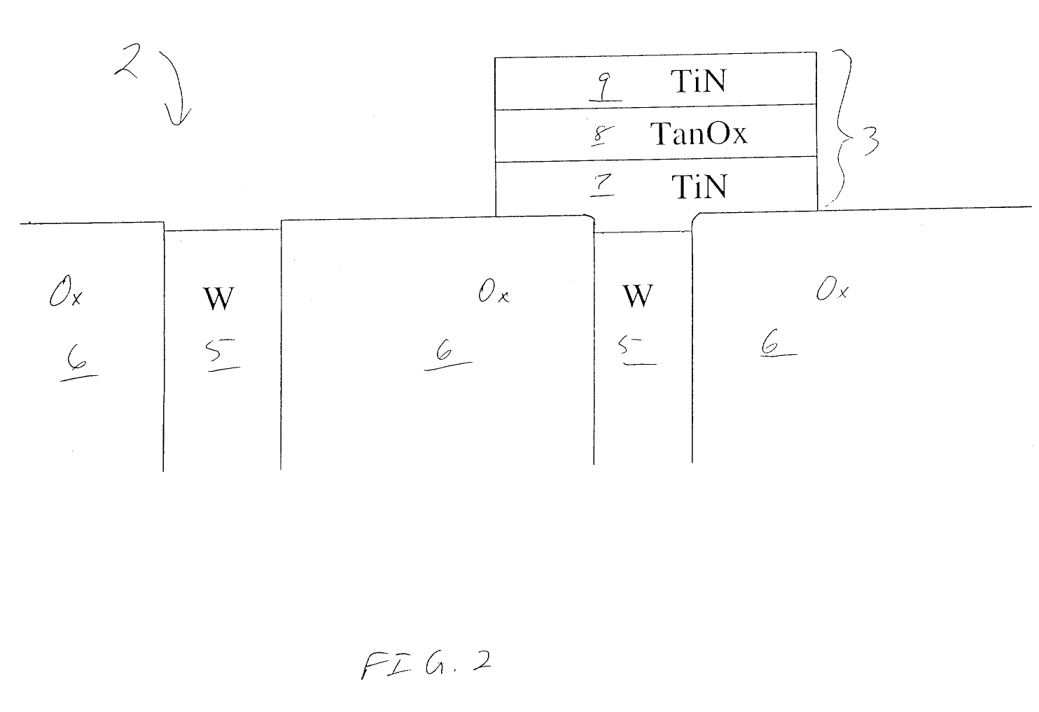

Referring again to the drawings, FIG. 2 shows the same wafer portion, 2, following a sulfuric acid clean that removed the titanium fluoride nodules, 4, from the highdensity capacitor, 3. In the best mode application, a semiconductor wafer is subjected to an additional cleaning process following the typical ash, wet clean, and dry clean processes used to make high-density capacitors, 3. Following the dry clean process (such as a CF₄/O₂ sidewall clean), the wafer is subjected to a sulfuric acid clean. As an example, a Mercury spray processor (made by FSI) may be used to clean the wafer with sulfuric acid at 55° C. for 10 minutes. However it is within the scope of this invention to perform the clean at any temperature up to 85° C. and for any length of time less than 40 minutes. After the sulfuric acid clean, the wafer is rinsed with deionized water using the same or different machine; and then the wafer is dried.

Various modifications to the invention as described above are within the scope of the claimed invention. For example, the invention is applicable in semiconductor wafers having different interconnect dielectric and metal materials or configurations. In addition, it is within the scope of this invention to use a sulfuric acid clean for titanium nitride or any other titanium containing surfaces located anywhere on a semiconductor wafer. Furthermore, halogens other than fluorine may be used to clean residues after etch or clean. Such halogens can be used singly or in combination, plus the halogens may exist as part of a larger molecule used in etch or clean processes. Moreover, the invention is applicable to many semiconductor technologies such as Si, BiCMOS, bipolar, SOI, strained silicon, microelectrical mechanical system (“MEMS”), or SiGe.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for cleaning high-density capacitors on a semiconductor wafer comprising:
cleaning said semiconductor wafers with sulfuric acid.

2. The method of claim 1 wherein said cleaning step follows a titanium nitride etch of said semiconductor wafer.

3. The method of claim 1 wherein said cleaning step follows a fluorocarbon plasma clean of said semiconductor wafer.

4. The method of claim 1 wherein said cleaning step is performed by a spray processor at a temperature below 85° C. and for a time less than 40 minutes.

5. The method of claim 1 further comprising the step of performing a deionized water rinse of said semiconductor wafer following said cleaning step.

6. The method of claim 5 further comprising the step of drying said semiconductor wafer following said deionized water rinse step.
